(19) United States
(12) Patent Application Publication
(10) Pub. No.: US 2011/0065252 A1
(43) Pub. Date: Mar. 17, 2011

(54) METHOD FOR FABRICATING PHASE CHANGE MEMORY DEVICE

(75) Inventor: Hideyuki NAKAMURA, Chuo-ku (JP)

(73) Assignee: ELPIDA MEMORY, INC., Tokyo (JP)

(21) Appl. No.: 12/882,843

(22) Filed: Sep. 15, 2010

(30) Foreign Application Priority Data
Sep. 16, 2009 (JP) 2009-214601

(51) Int. Cl. H01L 21/02

(52) U.S. Cl. 438/382; 257/E21.004

(57) ABSTRACT

A method for fabricating a phase change memory device comprises forming a heater electrode in an interlayer insulating film to penetrate through the interlayer insulating film, forming an insulating layer on the interlayer insulating film in which the heater electrode is formed, forming a tapered hole in the insulating layer to expose a center of a top surface of the heater electrode, thinning the insulating layer by removing a part of the insulating layer in which the hole is formed, and forming a phase change layer on the insulating layer after thinning the insulating layer so as to fill the hole.

### BACKGROUND OF THE INVENTION

1. Field of the Invention

The present invention relates to a method for fabricating a phase change memory device, and particularly to a method for fabricating a phase change memory device having a phase change layer electrically connected to a heater electrode.

2. Description of Related Art

A phase change memory device is a device that uses a phenomenon for data storage, the phenomenon in which electrical resistance is varied due to a change in the crystalline state of a phase change layer. In other words, when the phase change layer is in an amorphous phase having a high resistance, this state corresponds to “1” of binary data, whereas when it is in a crystalline phase having a low resistance, this state corresponds to “0”, whereby the phase change memory device can store digital data.

This change of the crystalline state is induced by applying thermal energy to the phase change layer. To this end, a method is adopted in which a heater electrode made of a metallic material having a high electrical resistance is disposed on a current path and brought into contact with a phase change layer, whereby the heat generated when electrical current is carried through the heater electrode is transmitted to the phase change layer.

In order to achieve lower power consumption of the phase change memory device, this method seeks to efficiently transfer heat that is generated in the heater electrode to the phase change layer. To reach this goal, for example, JP 2007-080978 discloses a method in which a phase change layer is provided on a heater electrode to be bent and is brought into contact with the end of the top surface of the heater electrode, whereby the contact area between the phase change layer and the heater electrode is reduced.

As discussed above, when the phase change layer is brought into contact with the end of the top surface of the heater electrode, the heat generated at the end of the heater electrode is transferred to the phase change layer. Because of this, the heat is spread not only to the phase change layer but also to the insulating film around the heater electrode, causing a decrease in heat transfer efficiency from the heater electrode to the phase change layer. Accordingly, in order to induce phase changes in such a situation, a problem arises in which the current to be carried through the heater electrode has to be increased.

From this viewpoint, it is preferable that the phase change layer and the heater electrode be in contact with each other near the center of the top surface of the heater electrode, but not at the end of top surface of the heater electrode. However, in the method described in JP 2007-080978, when it is desired to bring the phase change layer into contact with the heater electrode at the center of the top surface of the heater electrode, the contact area itself can become larger. This leads to widening the area (phase change area) of the phase change layer, in which the crystalline state is changed by receiving heat from the heater electrode, and thus to increasing the amount of heat necessary to complete the phase change.

From the discussions above, in order to achieve lower power consumption of the phase change memory device, there is a strong demand to solve the aforementioned problems between the heater electrode and the phase change layer, and to reduce the amount of energy to be consumed by the heater electrode during phase changes.

### SUMMARY

In one embodiment, there is provided a method for fabricating a phase change memory device, wherein the method comprises forming a heater electrode in an interlayer insulating film to penetrate through the interlayer insulating film, forming an insulating layer on the interlayer insulating film in which the heater electrode is formed, forming a tapered hole in the insulating layer to expose a center of a top surface of the heater electrode, thinning the insulating layer by removing a part of the insulating layer in which the hole is formed, and forming a phase change layer on the insulating layer after thinning the insulating layer so as to fill the hole.

In another embodiment, there is provided a method for fabricating a phase change memory device, wherein the method comprises forming a heater electrode in an interlayer insulating film to penetrate through the interlayer insulating film, forming a first insulating film on the interlayer insulating film in which the heater electrode is formed, forming a second insulating film on the first insulating film, forming a tapered hole in the first and second insulating films to expose a center of a top surface of the heater electrode, removing at least a portion of the second insulating film in which the hole is formed, and forming a phase change layer on the insulating layer after removing at least the portion of the second insulating film so as to fill the hole.

In this fabricating method, the phase change layer is formed so as to fill the tapered hole penetrating through the insulating layer on the heater electrode and exposing the center of the top surface of the heater electrode. Consequently, the connection with a small contact area between the phase change layer and the heater electrode can be obtained at the center of the heater electrode. In addition, the insulating layer in which the tapered hole is formed is reduced in thickness, whereby the cross sectional area of the upper part of a contact of the phase change layer inside the hole taken along a direction parallel to the film surface can be made smaller than the minimum feature size determined by the resolution capability of the processing. This prevents the phase change area of the phase change layer from being expanded. Accordingly, the amount of energy that will be consumed by the heater electrode during phase changes can be reduced to achieve lower power consumption of the phase change memory device.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross sectional view showing a first embodiment of a PRAM as a phase change memory device of the present invention;

FIG. 2 is a flow chart illustrative of a method for fabricating the PRAM in the first embodiment of the present invention;

FIGS. 3 to 10 are step diagrams illustrative of the method for fabricating the PRAM in the first embodiment of the present invention; and

FIGS. 11 to 13 are step diagrams illustrative of the method for fabricating a PRAM in a second embodiment of the present invention.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

In this specification, a Phase change Random Access Memory (PRAM) having a Metal Oxide Semiconductor (MOS) transistor as a switching device will be explained as an example of a phase change memory device to be produced by a method according to the invention. It should be noted that since the MOS transistor is publicly known, description of its detailed structure and fabricating method will be omitted below.

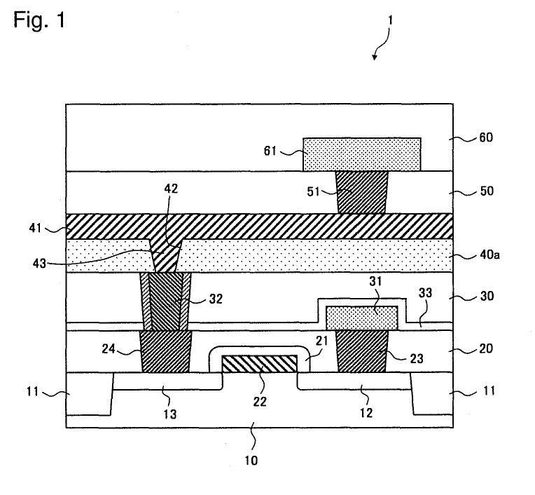

First, a method for fabricating a PRAM as a phase change memory device in a first embodiment of the present invention will be described with reference to FIGS. 1 to 10.

FIG. 1 is a cross sectional view of the PRAM to be produced by the fabricating method of this embodiment, showing a cross section of a memory cell region, in which a MOS transistor is formed, taken along a direction perpendicular to a semiconductor substrate.

PRAM 1 of this embodiment includes a MOS transistor as a switching device and phase change layer 41 as a memory element.

The MOS transistor is formed in an area surrounded by isolation region 11 on semiconductor substrate 10 made of silicon, the MOS transistor comprising diffusion regions 12, 13 and gate electrode 22 whose surface is covered with insulating film 21. One diffusion region 12 of the MOS transistor is connected to wiring 31 through contact plug 23 provided in interlayer insulating film 20, and other diffusion region 13 is connected to heater electrode 32 through contact plug 24 provided in interlayer insulating film 20.

Heater electrode 32 is provided in interlayer insulating film 30 formed on interlayer insulating film 20 through insulating film 33. Phase change layer 41 is provided on interlayer insulating film 30 through lower insulating film 40a. Phase change layer 41 comprises contact 43 formed in hole 42 provided in lower insulating film 40a. Phase change layer 41 and heater electrode 32 are electrically connected to each other through contact 43. In addition, through contact plug 51 provided in interlayer insulating film 50, phase change layer 41 is connected to wiring 61 provided in interlayer insulating film 60.

Contact 43 of phase change layer 41 has a tapered shape in which the cross sectional area taken perpendicular to the extending direction of contact 43 becomes gradually smaller from top to bottom. On this account, phase change layer 41 is connected to heater electrode 32 in a small contact area and at the center of the top surface thereof. Consequently, the heat generated in the center of heater electrode 32 by electrical current carried through heater electrode 32 is transferred to phase change layer 41, without being spread around heater electrode 32. As a result, the heat transfer efficiency from heater electrode 32 to phase change layer 41 can be improved. Further, as described later, contact 43 to be formed in hole 42 is configured such that the cross sectional area of its upper part taken along a direction parallel to the film surface is made smaller than the minimum feature size determined by the resolution capability of the processing. This prevents the area (phase change area) in which the crystalline state of phase change layer 41 is changed from being expanded due to the heat from heater electrode 32. Therefore, it is possible to efficiently use the heat generated from heater electrode 32 for changing the crystalline state of phase change layer 41. In this way, the current that is necessary for phase changes can be made smaller, and the energy to be consumed by the heater electrode can be reduced. Thus, it is made possible to achieve lower power consumption of the PRAM.

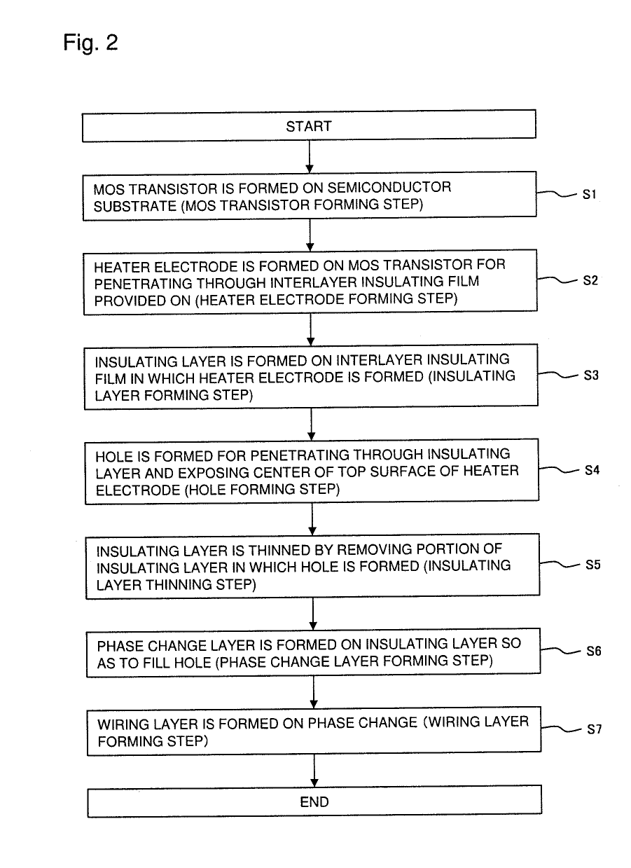

Next, the individual steps of the method for fabricating the PRAM of this embodiment will be described step by step with reference to FIGS. 2 to 10.

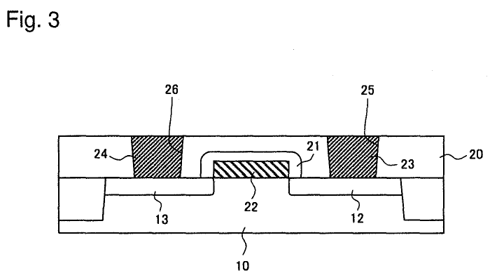

FIG. 2 is a flow chart illustrative of the method for fabricating the PRAM of this embodiment. FIGS. 3 to 10 are cross sectional views showing the memory cell region of the PRAM in each step, corresponding to FIG. 1. Here, as described above, the explanation of the fabricating method for the MOS transistor elements will be omitted, and the individual steps from after formation of the MOS transistor to the completion of the PRAM (memory cell region) will be described in detail.

(Step S1: MOS Transistor Forming Step)

In this step, after forming the MOS transistor, as shown in FIG. 3, contact plugs 23, 24 connected to diffusion regions 12, 13 of the MOS transistor are formed.

Interlayer insulating film 20 made of phosphoarsenosilicate glass having a thickness of 800 nm is formed to bury gate electrode 22 covered with insulating film 21. After planarizing the surface of interlayer insulating film 20 by Chemical Mechanical Polishing (CMP), holes 25, 26 are formed in interlayer insulating film 20 by lithography and dry etching in order to expose the surfaces of diffusion regions 12, 13 therebelow. A titanium film having a thickness of 15 nm, a titanium nitride film having a thickness of 15 nm, and a tungsten film having a thickness of 120 nm are sequentially deposited to fill these holes 25, 26. Then, excess titanium, titanium nitride, and tungsten on interlayer insulating film 20 are removed by CMP, whereby contact plugs 23, 24 are formed.

(Step S2: Heater Electrode Forming Step)

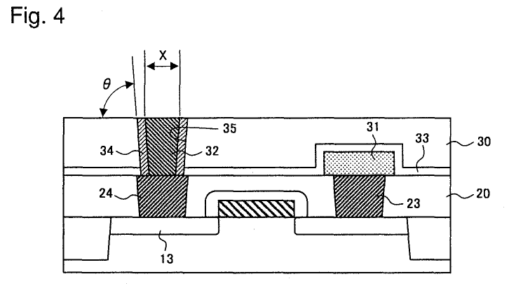

In this step, as shown in FIG. 4, heater electrode 32 is formed on contact plug 24 connected to diffusion region 13 of the MOS transistor.

On interlayer insulating film 20, a tungsten nitride film having a thickness of 10 nm and a tungsten film having a thickness of 40 nm and a silicon nitride film having a thickness of 100 nm are sequentially deposited by Chemical Vapor Deposition (CVD). Then, the pattern of wiring 31 connected to one contact plug 23 is formed by lithography and dry etching. Thereafter, insulating film 33, which is a silicon nitride film having a thickness of 20 nm, is formed by CVD, and interlayer insulating film 30, which is a silicon oxide film having a thickness of 300 nm, is then deposited by High Density Plasma (HDP)-CVD.

After planarizing the surface of interlayer insulating film 30 by CMP, hole 35 is formed in interlayer insulating film 30 by lithography and dry etching in order to expose the top surface of other contact plug 24 therebelow. A silicon nitride film having a thickness of 65 nm is deposited on the inner wall of hole 35 by CVD and etched back to cover the inner side surface of hole 35, forming side wall 34. Then, hole 35 in which side wall 34 is formed is filled with titanium nitride, the excess of which is removed by CMP from interlayer insulating film 30, whereby heater electrode 32 is completed. Diameter X of heater electrode 32 is about 60 nm, and angle θ of the outer side surface of heater electrode 32 with respect to the film surface is about 89°.

Here, a material with electrical resistance higher than that of the heater electrode, such as titanium silicon nitride (having a thickness of 15 nm) may be sandwiched between the side wall made of the silicon nitride film and the heater electrode made of titanium nitride. Consequently, the heat generation efficiency of heater electrode 32 is improved to allow the current supplied to heater electrode 32 to be further reduced.

(Step S3: Insulating Layer Forming Step)

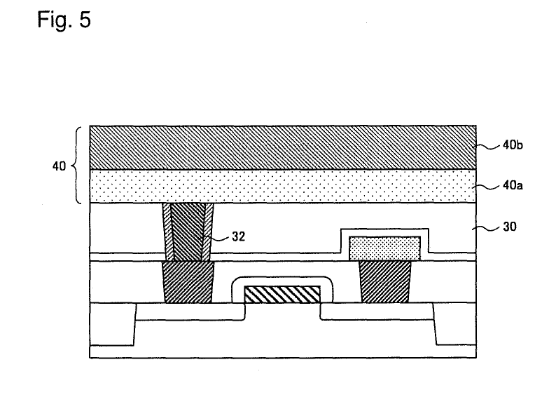

In this step, insulating layer 40 is formed on interlayer insulating film 30 in which heater electrode 32 is formed. In this embodiment, in order to facilitate the etching process in an insulating layer thinning step to be described, as shown in FIG. 5, insulating layer 40 is formed to be a two-layer structure consisting of lower insulating film 40a and upper insulating film 40b.

First, on interlayer insulating film 30 in which heater electrode 32 is formed, lower insulating film (first insulating film) 40a made of a silicon nitride film having a thickness of 50 nm is formed by low-pressure CVD. This process is conducted in a batch-type vertical furnace. Dichlorosilane and ammonia are used as raw material gases. The flow rates of the raw material gases are 1.25 cm³/s (75 sccm) and 12.5 cm³/s (750 sccm), respectively, and the heating temperature and pressure thereof are 630° C. and 300 Pa, respectively.

Subsequently, on lower insulating film 40a, upper insulating film (second insulating film) 40b made of a silicon oxide film having a thickness of 65 nm is formed by low-pressure CVD. This process is conducted in a batch-type vertical furnace. The flow rates of the raw material gases in this process are as follows: 4.17 cm³/s (250 sccm) for TEOS (tetraethoxysilane), 38.3 cm³/s (2300 sccm) for oxygen, 11.7 cm³/s (700 sccm) for helium, and 5.0 cm³/s (250 sccm) for argon. The heating temperature and pressure are 360° C. and 400 Pa, respectively.

(Step S4: Hole Forming Step)

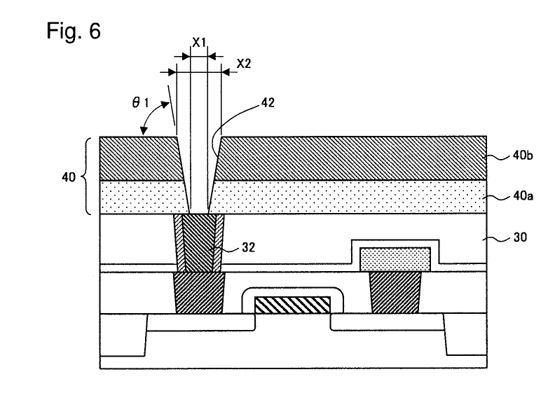

In this step, as shown in FIG. 6, hole 42 is formed, which penetrates through insulating layer 40 consisting of lower insulating film 40a and upper insulating film 40b.

First, a resist is applied on upper insulating film 40b. Then, the resist is developed such that only an area of upper insulating film 40b corresponding to heater electrode 32 is exposed, whereby a resist pattern (not shown) is formed. Thereafter, the resist pattern is used as a mask to dry etch upper insulating film 40b and lower insulating film 40a by parallel-plate Reactive Ion Etching (RIE) for forming hole 42 penetrating therethrough. The conditions for this etching process are as follows: The source power is 3000 W, pressure is 15 mTorr, wafer temperature is 60° C., and flow rates of process gases are 0.33 cm³/s (20 sccm) for hexafluoro-1,3-butadiene, 0.83 cm³/s (50 sccm) for trifluoromethane, 0.33 cm³/s (20 sccm) for oxygen, and 3.33 cm³/s (200 sccm) for argon.

After this process, Hole 42 has opening size (diameter) X1 of 29 to 31 nm at the bottom surface of lower insulating film 40a, and opening size (diameter) X2 of 50 to 62.3 nm at the top surface of upper insulating film 40b. Angle θ1 of the inner side surface of hole 42 with respect to the film surface is about 82 to 85°.

The forming position of hole 42 is adjusted such that the bottom of this tapered hole 42 is positioned at the center of the top surface of heater electrode 32. Here, hole 42 is preferably formed by adjusting the dry etching conditions such that the taper angle of the inner side surface (a tilt angle with respect to a direction parallel to the semiconductor substrate) of hole 42 is smaller than that of the outer surface of heater electrode 32. This allows the exposed area of the top surface of heater electrode 32 to be reduced. and thus, in a phase change layer forming step to be described, the contact area between phase change layer 41 and heater electrode 32 can be reduced.

(Step S5: Insulating Layer Thinning Step)

The opening size at the top surface of hole 42 is preferably made as small as possible because it determines the size of the phase change area described above. However, in the aforementioned dry etching process, there are limitations on processing for reducing the upper opening size of hole 42. On this account, in this step, for the purpose of making the upper opening size of hole 42 smaller than the minimum feature size determined by the resolution capability of the processing, a portion of insulating layer 40 is removed to reduce the thickness of insulating layer 40.

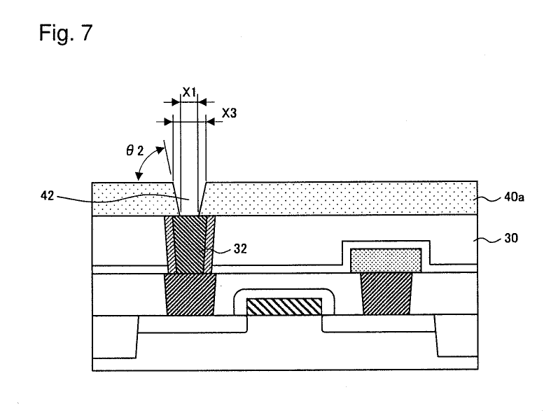

In this embodiment, as shown in FIG. 7, upper insulating film 40b, which is a portion of insulating layer 40, is removed by wet etching using buffered hydrogen fluoride, until lower insulating film 40a is exposed. The process conditions are as follows: The ratio of hydrofluoric acid (HF) to ammoniumhydroxide (NH₄OH) is 0.1 to 20 in buffered hydrogen fluoride, the temperature of the chemical solution (buffered hydrogen fluoride) is 65° C., and the etching selection ratio of the silicon oxide film (upper insulating film 40b) to the silicon nitride film (lower insulating film 40a) is 100 or more.

After this process is completed, Hole 42 has opening size X1 of 29 to 31 nm at the bottom surface of lower insulating film 40a, indicating no change from the formation of hole 42 by dry etching. On the other hand, opening size X3 at the top surface of lower insulating film 40a is 38.7 to 44.1 nm, and this size has been further reduced so that it is smaller than that of opening size X2 at the top surface of upper insulating film 40b by about 11 to 18 nm. Angle θ2 of the inner side surface of hole 42 with respect to the film surface is about 82° to 85°, indicating no change from the formation of hole 42 by dry etching.

As described above, part 40b of insulating layer 40, in which tapered hole 42 is formed, is removed by wet etching in order to reduce the thickness, whereby it is possible to make the upper opening size of hole 42 smaller than the minimum feature size determined by the resolution capability of the processing.

(Step S6: Phase Change Layer Forming Step)

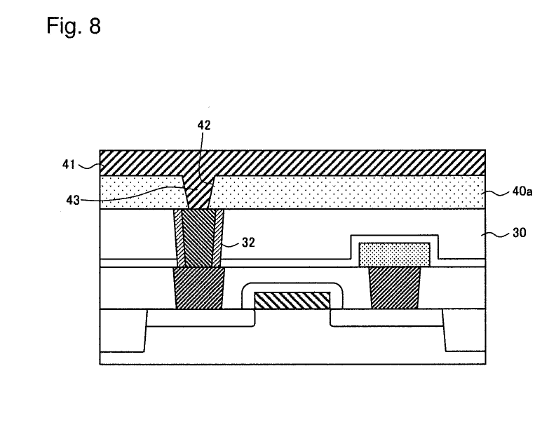

In this step, as shown in FIG. 8, phase change layer 41 is formed on lower insulating film 40a so as to fill hole 42.

First, a titanium nitride film having a thickness of 60 nm, a titanium film having a thickness of 1 nm, a Ge—Sb—Te (GST) film having a thickness of 100 nm made of a germanium-antimony-tellurium material, and a Non-doped Silica Glass (NSG) film having a thickness of 150 nm are deposited on lower insulating film 40a so as to fill hole 42, so that phase change layer 41 is formed. At the same time, tapered contact 43 is formed in hole 42. The bottom of contact 43 physically contacts the center of the top surface of heater electrode 32, whereby phase change layer 41 and heater electrode 32 are electrically connected to each other.

Thereafter, a phase change layer in the peripheral circuit region (not shown) is removed by lithography and dry etching, and thus the pattern of phase change layer 41 is completed.

(Step S7: Wiring Layer Forming Step)

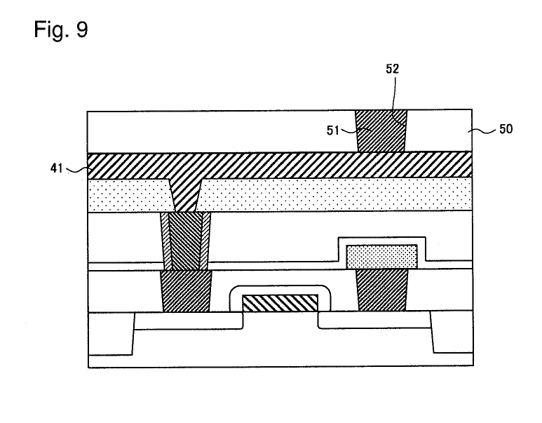

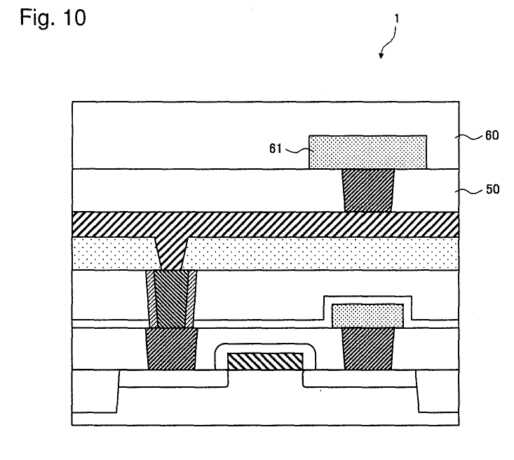

In this step, as shown in FIG. 9, contact plug 51 connected to phase change layer 41 is formed on phase change layer 41, and then as shown in FIG. 10, a wiring layer including wiring 61 connected to contact plug 51 is formed.

First, interlayer insulating film 50 is formed on phase change layer 41 as below. Then, after depositing a NSG film having a thickness of 100 nm, a silicon oxide film having a thickness of 600 nm is deposited by HDP-CVD. Next, CMP processing is applied to this silicon oxide film until the memory cell region and the peripheral circuit area are plagiarized, and then a silicon oxide film having a thickness of 200 nm is deposited thereon by CVD. In this way, interlayer insulating film 50 is formed on phase change layer 41, interlayer insulating film 50 comprising the NSG film and the two-layered silicon oxide films formed respectively by HDP-CVD and by CVD. Thereafter, hole 52 is formed by lithography and dry etching to expose a portion of phase change layer 41. A titanium nitride film having a thickness of 50 nm and a tungsten film having a thickness of 200 nm are sequentially deposited to fill hole 52. Then, excess titanium nitride and tungsten on interlayer insulating film 50 are removed by CMP, whereby contact plug 51 is formed.

Next, as shown in FIG. 10, after sequentially depositing a titanium film having a thickness of 10 nm, a titanium nitride film having a thickness of 70 nm and an aluminum having a thickness of 270 nm on interlayer insulating film 50, a silicon oxide film having a thickness of 250 nm is deposited thereon by CVD. Then, the pattern of wiring 61 is formed by lithography and dry etching and subsequently, by means of HDP-CVD, wiring 61 is buried with interlayer insulating film 60 made of a silicon oxide film having a thickness of 1000 nm. Finally, the surface of interlayer insulating film 60 is planarized by CMP, whereby the wiring layer is formed.

Thereafter, an upper wiring layer is further formed as necessary, and PRAM 1 is completed.

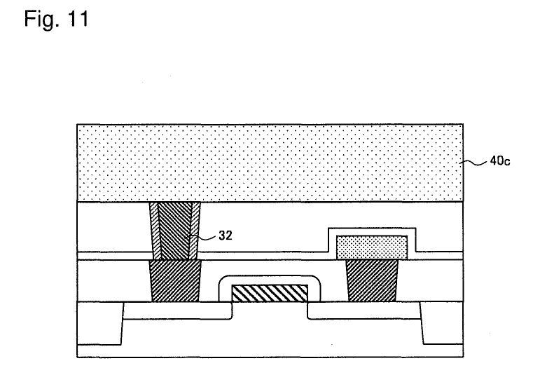

FIGS. 11 to 13 are diagrams showing steps from the insulating layer forming step (Step S3) to the insulating layer thinning step (Step S5) in a second embodiment.

As described above, in the insulating layer forming step of the embodiment shown in FIGS. 5 to 7, insulating layer 40 having a two-layer structure consisting of upper insulating film 40b and lower insulating film 40a was formed on heater electrode 32. On the other hand, in this embodiment, as shown in FIG. 11, single-layered insulating layer 40c made of a silicon oxide film having a thickness of 115 nm is formed on heater electrode 32 by low-pressure CVD.

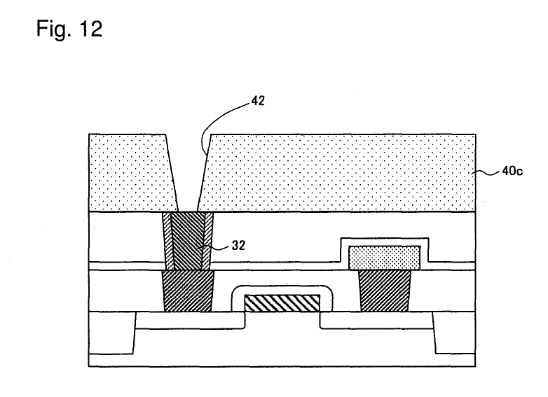

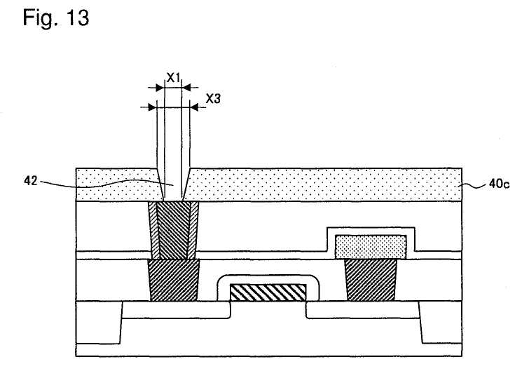

In this case, in the hole forming step shown in FIG. 12, hole 42 is formed for penetrating through insulating layer 40c and exposing heater electrode 32 therebelow. Thereafter, in the insulating layer thinning step, as shown in FIG. 13, a portion of insulating layer 40c is removed by wet etching in order to reduce the thickness of insulating layer 40c. The processing time for wet etching is controlled such that such that the thickness of the remaining insulating layer is 50 nm, so that insulating layer 40c can be formed in the same shape as in FIG. 7. In addition, in order to reduce variations in the thickness of the remaining layer among wafers caused by wet etching, the etching rate thereof is preferably reduced by adjusting the mixing ratio of chemical solutions for wet etching. In this case, a protective film, such as a silicon nitride film, having a high wet etching selection ratio is formed on the inner side surface of hole 42 to prevent the expansion of the opening sizes X1, X3 of hole 42 after the insulating layer thinning step is completed.

It is apparent that the present invention is not limited to the above embodiments, but may be modified and changed without departing from the scope and spirit of the invention.

What is claimed is:

1. A method for fabricating a phase change memory device, comprising:
forming a heater electrode in an interlayer insulating film to penetrate through the interlayer insulating film;
forming an insulating layer on the interlayer insulating film in which the heater electrode is formed;
forming a tapered hole in the insulating layer to expose a center of a top surface of the heater electrode;
thinning the insulating layer by removing a portion of the insulating layer in which the hole is formed; and
forming a phase change layer on the insulating layer after thinning the insulating layer so as to fill the hole.

2. The method for fabricating a phase change memory device according to claim 1, wherein the thinning the insulating layer comprises removing the portion of the insulating layer by wet etching.

3. The method for fabricating a phase change memory device according to claim 2, further comprising forming a wet etching protective film in the hole before thinning the insulating layer.

4. The method for fabricating a phase change memory device according to claim 1, wherein a taper angle of an inner side surface of the hole is smaller than that of an outer side surface of the heater electrode.

5. The method for fabricating a phase change memory device according to claim 1, wherein the forming the heater electrode comprises forming a layer made of a material having an electrical resistance higher than that of the heater electrode on an outer side surface of the heater electrode.

6. A method for fabricating a phase change memory device, comprising:
forming a heater electrode in an interlayer insulating film to penetrate through the interlayer insulating film;
forming a first insulating film on the interlayer insulating film in which the heater electrode is formed;
forming a second insulating film on the first insulating film;
forming a tapered hole in the first and second insulating films to expose a center of a top surface of the heater electrode;
removing at least a portion of the second insulating film in which the hole is formed; and
forming a phase change layer on the insulating layer after removing at least the portion of the second insulating film so as to fill the hole.

7. The method for fabricating a phase change memory device according to claim 6, wherein removing at least the portion of the second insulating film comprises removing at least the portion of the second insulating film by wet etching.

8. The method for fabricating a phase change memory device according to claim 7, wherein an etching rate of the second insulating film is higher than that of the first insulating film.

9. The method for fabricating a phase change memory device according to claim 6, wherein the first insulating film is a silicon nitride film, and wherein the second insulating film is a silicon oxide film.

10. The method for fabricating a phase change memory device according to claim 6, wherein a taper angle of an inner side surface of the hole is smaller than that of an outer side surface of the heater electrode.

11. The method for fabricating a phase change memory device according to claim 6, wherein the forming the heater electrode comprises forming a layer made of a material having an electrical resistance higher than that of the heater electrode on an outer side surface of the heater electrode.
